(19) United States
(12) Patent Application Publication
(10) Pub. No.: US 2019/0081362 A1
(43) Pub. Date: Mar. 14, 2019

(54) Over-Molded Printed Circuit Board Connector

(71) Applicant: Apple Inc., Cupertino, CA (US)

(72) Inventors: Jonathan C. Wilson, San Jose, CA (US); Tianhao Li, Santa Clara, CA (US); Nathan J. Bohney, Campbell, CA (US)

(21) Appl. No.: 15/857,099

(22) Filed: Dec. 28, 2017

Related U.S. Application Data
(60) Provisional application No. 62/555,836, filed on Sep. 8, 2017.

(51) Int. Cl. H01M 10/42; H01R 12/79; H05K 5/00; H01M 2/10; H01M 10/48

(52) U.S. Cl. CPC H01M 10/425; H01R 12/79; H05K 5/0034; H05K 1/18; H01M 10/486; H01M 10/482; H01M 2/1022

(57) ABSTRACT

An over-molded printed circuit board may be used in a battery pack. The over-molded printed circuit board can include a printed circuit board having electronic components, such as battery management circuitry, disposed thereon. A flex connector can be attached to the printed circuit board. An over-mold can formed about the printed circuit board, for example, by injection molding an epoxy resin, polyamide, or other suitable material. The over-mold may facilitate routing of the flex connector at a desired angle from the battery back and may also have a geometry that provides a supporting mechanical interface between the cells of the battery pack and the printed circuit board. Battery packs so constructed may be installed in electronic devices, such as mobile telephones, smart phones, tablet computers, laptop computers, media players, etc.

### BACKGROUND

Many electronic devices rely on internal rechargeable battery packs. Such electronic devices may include mobile telephones, tablet computers, laptop computers, smart watches, and the like. Additionally, peripherals for use with such devices, such as keyboards, mice, headphones, and the like may also use internal rechargeable battery packs. Internal rechargeable battery packs used in these and other devices may include components in addition to the battery terminals themselves that must be connected to various systems within the electronic devices. For example, battery packs may incorporate circuitry that provides temperature, voltage, and/or current information to a battery management system within the electronic device, but external to the battery pack. Other circuits, systems, and/or devices may also be included within the battery pack. Collectively, these other components within the battery pack are referred to herein as “battery management circuitry,” and the connections with other systems within the electronic device are referred to herein as “battery management connections.”

To facilitate connections of the battery terminals and the battery management circuitry, both to each other and to various components external to the battery pack, printed circuit boards (PCBs) may be used. The battery management circuitry may be located on such printed circuit boards. These printed circuit boards may be connected to other systems or components within the electronic device by a flexible printed circuit board connector, which may also be known, for example, as a “flexible printed circuit” or simply a “flex.” At one end, this flex may be connected to the battery pack, including connections to the battery terminals and the battery management connections. At the other end, this flex may be connected to a board-to-board connector.

In many electronic devices, space for the battery pack and the associated connections is at a premium. Disclosed herein are various embodiments that can provide improved space utilization efficiency.

### SUMMARY

Disclosed herein is an over-molded printed circuit board for use in a battery pack. The over-molded printed circuit board can include a printed circuit board having one or more electronic components disposed thereon. The electronic components may comprise battery management circuitry configured to provide information about one or more of battery cell current, battery cell voltage, and battery cell temperature for the battery back. The over-molded printed circuit board can also include a flex connector attached to the printed circuit board. The flex connector can include an inter-board connector for providing battery power and the battery management information to other components or systems of an electronic device. The over-molded printed circuit board may also include an over-mold formed about the printed circuit board.

The over-mold may facilitate routing of the flex connector at a desired angle from the battery back. The over-mold may also have a geometry that provides a supporting mechanical interface between the one or more battery cells and the printed circuit board. The over-mold may be formed by injection molding an epoxy resin or polyamide material about the printed circuit board. The over-mold may also include a plurality of test ports that allow electrical connection to test terminals located on the printed circuit board.

Battery packs comprising one or more battery cells may be constructed using the over-molded printed circuit board. The battery packs may be installed in electronic devices, such as mobile telephones, smart phones, tablet computers, laptop computers, media players, and the like, as well as the peripherals associated therewith, such as input devices (e.g., keyboards, mice, touchpads, tablets, etc.), output devices (e.g., headphones or speakers), storage devices, or other peripheral types. A battery pack including the over-molded printed circuit board may also include mechanisms for further securing the over-molded printed circuit board to the battery pack, such as an adhesive tape, and may also include other components, such as a plastic cap to protect the over-molded printed circuit board and other components.

A battery pack as described above may be constructed by assembling a printed circuit board, attaching a flex connector to the printed circuit board, over-molding the printed circuit board to form an over-mold, and attaching the over-molded printed circuit board to one or more cell leads of the battery pack. Over-molding the printed circuit board may be performed by injection molding an epoxy resin or polyamide material about the printed circuit board. Construction of the battery pack can further include one or more of rotating the over-molded printed circuit board into a desired orientation and further mechanically securing the over-molded printed circuit board to the battery pack.

### BRIEF DESCRIPTION OF THE DRAWINGS

FIG. 1 illustrates a block diagram of an electronic device including an internal rechargeable battery pack.

FIG. 2A illustrates an isometric view of a battery pack including a PCB, flex connector, and over-mold.

FIG. 2B illustrates a side view of a battery pack including a PCB, flex connector, and over-mold.

FIG. 3A illustrates an isometric view of an over-molded printed circuit board and a flex connector.

FIG. 3B illustrates a side view of an over-molded printed circuit board and a flex connector.

FIG. 3C illustrates a side view of an over-molded printed circuit board and a flex connector in which the over-mold has been rendered translucent.

FIG. 4 illustrates a process for assembling a battery pack including an over-molded printed circuit board.

### DETAILED DESCRIPTION

In the following description, for purposes of explanation, numerous specific details are set forth to provide a thorough understanding of the disclosed concepts. As part of this description, some of this disclosure's drawings represent structures and devices in block diagram form for sake of simplicity. In the interest of clarity, not all features of an actual implementation are described in this disclosure. Moreover, the language used in this disclosure has been selected for readability and instructional purposes, has not been selected to delineate or circumscribe the disclosed subject matter. Rather the appended claims are intended for such purpose.

Various embodiments of the disclosed concepts are illustrated by way of example and not by way of limitation in the accompanying drawings in which like references indicate similar elements. For simplicity and clarity of illustration, where appropriate, reference numerals have been repeated among the different figures to indicate corresponding or analogous elements. In addition, numerous specific details are set forth in order to provide a thorough understanding of the implementations described herein. In other instances, methods, procedures and components have not been described in detail so as not to obscure the related relevant function being described. References to “an,” “one,” or “another” embodiment in this disclosure are not necessarily to the same or different embodiment, and they mean at least one. A given figure may be used to illustrate the features of more than one embodiment, or more than one species of the disclosure, and not all elements in the figure may be required for a given embodiment or species. A reference number, when provided in a given drawing, refers to the same element throughout the several drawings, though it may not be repeated in every drawing. The drawings are not to scale unless otherwise indicated, and the proportions of certain parts may be exaggerated to better illustrate details and features of the present disclosure.

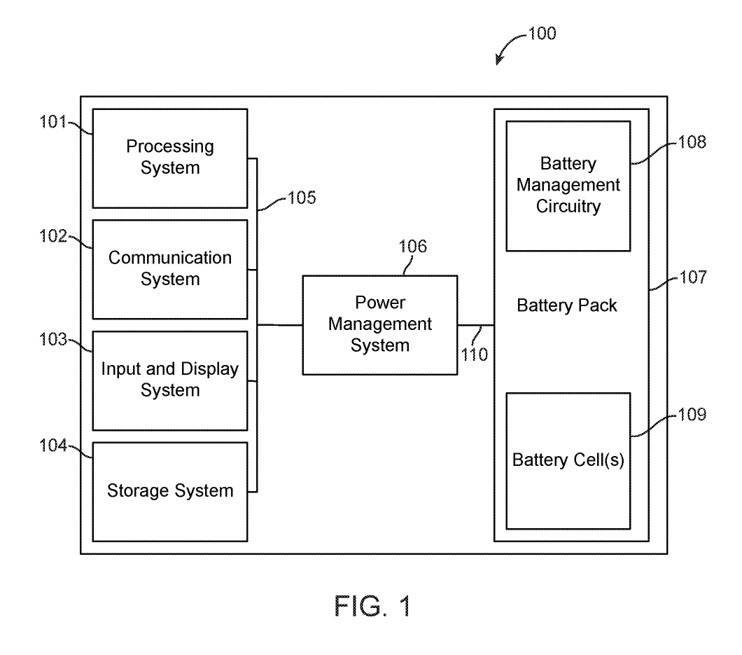

Illustrated in FIG. 1 is a block diagram of an electronic device 100 incorporating various features of the present disclosure. Electronic device 100 may be a mobile telephone, tablet computer, laptop computer, smart watch or the like, or may be a peripheral for use with such devices, such as a keyboard, mouse, tablet, headphone, etc. Electronic device 100 may include a plurality of systems, which are illustrated generically in FIG. 1. For example, electronic device 100 may include a processing system, which can include a central processing unit (CPU), a graphic processing unit (GPU), associated memory, etc. Electronic device 100 may also include a communication system 102. Depending on the type of device, communication system 102 may manage communication with a variety of external devices. Communication system 102 may implement a variety of communication protocols for communicating with external devices, including wired and wireless interfaces such as USB, Thunderbolt, FireWire, Ethernet, wireless Ethernet, Bluetooth, and/or cellular connections (including voice and/or data connections using GSM, LTE, etc.). Electronic device 100 may also include an input and display system 103 facilitating the input of information by a user of electronic device 100 as well as display of information to the user. In some embodiments, input and display system 103 may include a touch screen, including, for example, a multi-touch capable capacitive touch screen. Electronic device 100 may also include a storage system 104 incorporating volatile and/or non-volatile storage. These various systems may be interconnected by suitable connections (illustrated by communication bus 105), to allow for communication and cooperation among the various systems as required. It will be appreciated that depending on the particular nature of electronic device 100, one or more of the aforementioned systems may be omitted or combined with other systems, or additional systems (such as power management system 106, discussed below) may also be included.

Electronic device 100 may also include an internal rechargeable battery pack 107 and power management system 106. Internal rechargeable battery pack 107 may include a battery cell or cells 109 and battery management circuitry 108. The battery management circuitry may include any of a variety of circuits for providing information about battery pack 107, and particularly about battery cell(s) 109 to power management system 106. For example, the battery management circuitry may include circuitry that provides information about battery cell current, battery cell voltage, and/or battery cell temperature to power management system 106 via a battery interface 110 (discussed in greater detail below). Battery management circuitry 108 disposed on a printed circuit board (as further illustrated below). The terminals of battery cell(s) 109 may also be routed to such a printed circuit board. (It is these terminals that allow battery cell(s) 109 to power the various systems of electronic device, as well as be charged by/under control of power management system 106.) The printed circuit board may also include various terminals coupled to battery interface 110 by which battery management circuitry 108 communicates with power management system 106.

Power management system 106 may use the received information to perform a variety of functions. For example, power management system 106 may use such information to determine a state of charge of the battery pack and communicate that state of charge to processing system 101 and/or input and display system 103 for communication to a user. Additionally or alternatively, power management system 106 may use the received information to determine a state of health of the battery, also for communication to the user. Power management system 106 may also control charging of battery pack 107. This control may be based on all or a subset of the received information (including for example, battery current, voltage, and temperature) as well all or a subset of the information power management system 106 derives from such information, such as state of charge and battery health. In some embodiments, the battery charger may be included as part of power management system 106, while in other embodiments, the charger may be external to power management system 106 and/or external to electronic device 100, in which case power management system 106 may communicate with such charger either directly or via communication system 102. Finally, power management system 106 may also control the delivery of power from battery pack 107, and, more specifically, from battery cell(s) 109, to the various systems of electronic device 100.

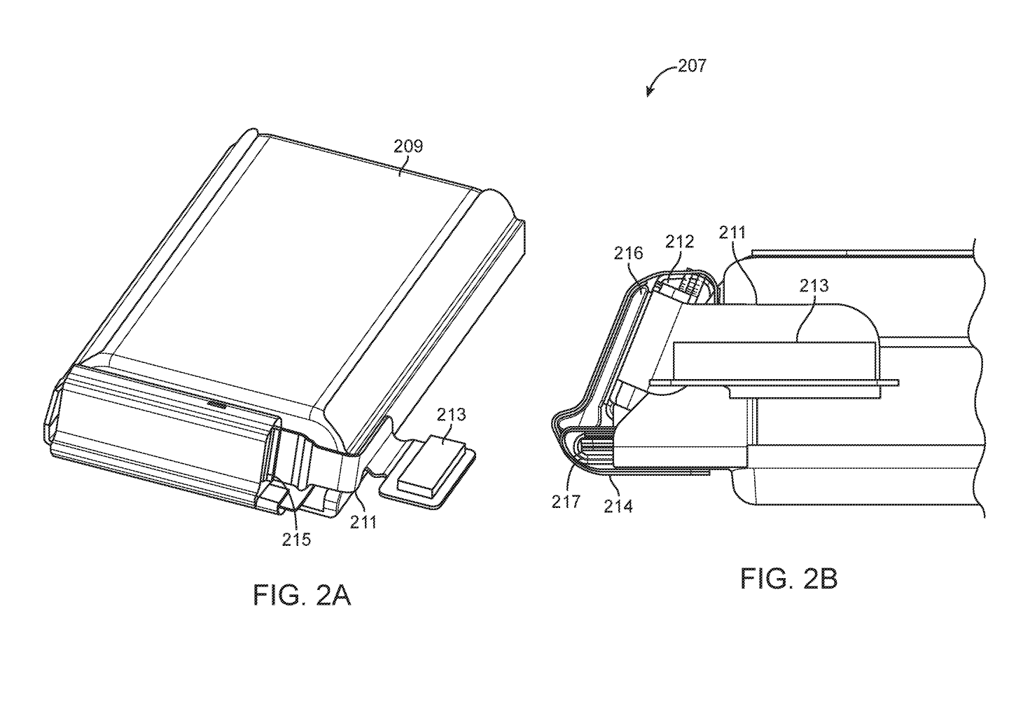

To perform the aforementioned or other functions, power management system receives power from battery cell(s) 109 and battery management circuitry 108 via battery interface 110. Battery interface 110 may be implemented through the use of a flexible printed circuit, also known as a flex connector or “flex.” An exemplary arrangement of a battery pack, printed circuit board, and flex connector is illustrated in FIGS. 2A and 2B. More specifically, FIG. 2A illustrates an isometric view of a battery pack 207 including a printed circuit board 215, flex circuit 211, and over-mold 212 (discussed in greater detail below). FIG. 2B illustrates a side view of one end of battery pack 207. Battery pack 207 includes battery cell(s) 209. Located at one end of battery cell(s) 209 are a variety of components, including printed circuit board 215, which can include the battery management circuitry 108 discussed above. This battery management circuitry 108, along with the battery power terminals, may be connected to battery inter-board connector 213 by a flexible printed circuit 211.

In some embodiments, it may be desirable to route flex circuit 211 at an angle. For example, such routing may be done for space savings, which can allow space for other components, increased battery capacity, and the like. A cap of plastic or other material could be fabricated and used to secure printed circuit board 215 and/or flex circuit 211 to the end of battery pack 207 at the desired angle. However, such caps may be undesirable because of increased space usage (negating some of the advantages of angled flex routing). Additionally, in some embodiments, such caps can lead to problems with water ingress, humidity, etc.

Rather than such a cap, battery pack 207 includes an over-mold 212 for printed circuit board 215. Over-mold 212 may be an injection molded epoxy resin that encapsulates printed circuit board 215 and the electronic components disposed thereon (e.g., battery management circuitry 108). Other materials besides an epoxy resin could also be used. For example, in some embodiments, a polyamide material may be injection molded around the printed circuit board 215 and the components disposed thereon. Over-mold 212 can also form a shape similar to the caps described above that hold printed circuit board 215 at an appropriate angle to support angled routing of flex circuit 211. More particularly, the geometry of the various surfaces of over-mold 212 may serve to provide a supporting mechanical interface between the battery cell(s) 209 (or other components of battery pack 207) and printed circuit board 215. Additionally, over-mold 212 can serve to protect the components disposed on printed circuit board 215.

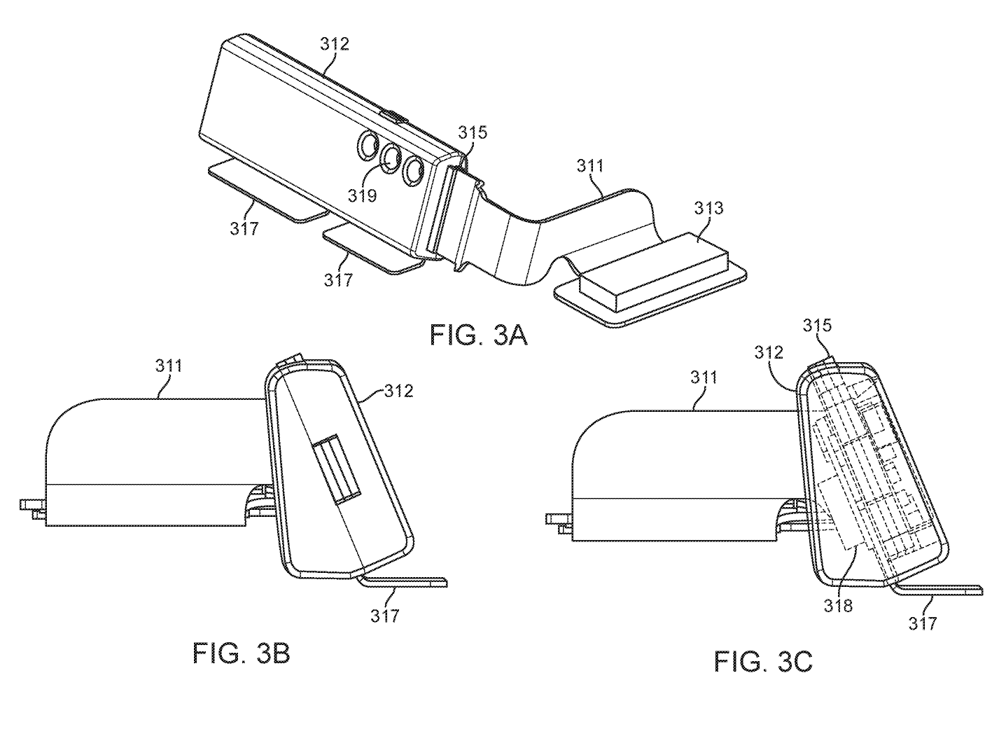

FIGS. 3A, 3B, and 3C illustrate over-mold 312 and the associated components in greater detail. More specifically, FIG. 3A is an isometric view of over-mold 312, flex circuit 311, and connector 313. FIG. 3B is a side view of over-mold 312 and flex circuit 311. FIG. 3C is a second side view in which over-mold 312 has been rendered translucent, allowing a view of printed circuit board 315 and components 318 to be seen.

As shown in FIGS. 3A-3C, over-mold 312 is disposed around printed circuit board 315. As noted above, over-mold 312 may be formed by injection molding an epoxy resin, a polyamide material, or other suitable encapsulating material around printed circuit board 315, thereby encapsulating printed circuit board 315 and the components 318 disposed thereon, for example, battery management circuitry 108. By controlling the shape and dimensions of the mold used in the injection molding process, printed circuit board may be made accessible through over-mold 312. For example, printed circuit board 315 may extend from the end of the over-mold as illustrated in FIG. 3A to facilitate connection of flex circuit 311. Additionally, test ports 319 may be formed in over-mold 312, allowing electrical connection to test terminals located on printed circuit board 315. These test ports and terminals may be used for various manufacturing, testing, and/or quality control purposes during assembly of battery pack 207.

Also illustrated in FIGS. 3A-3C are battery connection leads 317. Battery connection leads 317 allow connection of the terminals of battery cell(s) 209 to printed circuit board 315. In some embodiments, printed circuit board 315 and over-mold 312 may be formed in the configuration illustrated in FIGS. 3A-3C, in which the initial orientation of battery connection leads 317 is opposite their final, assembled orientation as illustrated in FIGS. 2A and 2B. Thus, printed circuit board 315, with overmold 312, may be attached in an “inverted” position to battery terminals (not shown) extending from battery cell(s) 209 (FIGS. 2A and 2B). Printed circuit board 315, with overmold 312, may then be rotated (clockwise in the plane of FIG. 2; counterclockwise in the plane of FIGS. 3B and 3C) into the position illustrated in FIG. 2. Thus, battery connection leads 217 are bent into a U-shape, and over-mold 212 is disposed against the end of battery cell(s) 209 as illustrated in FIGS. 2A and 2B.

As part of the assembly process described in the preceding paragraph, an adhesive tape 214 may be provided to wrap around and help with securing the various components. For example, adhesive tape 214 may be adhered to the lower portion of the pouch containing battery cell(s) 209 or to an intermediate surface otherwise associated with the battery pack. This adhesive tape may wrap around over-mold 212 and may be adhered to some other component or components of the battery pack to help secure the over-molded printed circuit board and flex connector in the desired position. An additional plastic cap component 216 may also be provided to protect over-mold 212, printed circuit board 215, and other components during installation and assembly. This plastic cap may be constructed in a manner generally similar to the caps discussed above, but may be substantially smaller because it does not need to provide supporting forces for printed circuit board 215. Thus, such a plastic cap 216 may avoid the disadvantages associated with prior art plastic caps discussed above.

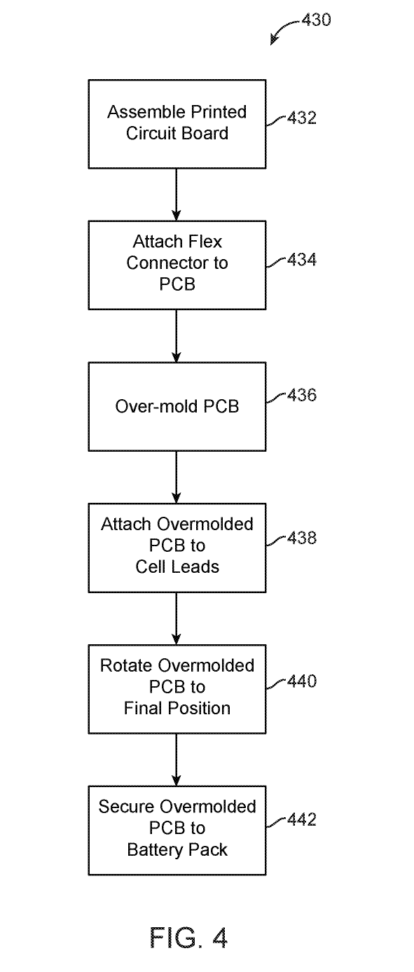

FIG. 4 illustrates a process 430 for assembling a battery pack in accordance with certain teachings of the present disclosure. The process can begin at block 432 with assembling a printed circuit board. This printed circuit board may include various battery management circuitry 108 as described above. In block 434, a flex connector may be attached to the printed circuit board. In block 436, the printed circuit board may be over-molded with an epoxy resin, polyamide, or other suitable encapsulating material as described above. Blocks 434 and 436 may be completed in any order, depending on the particular configuration of a given embodiment. At block 438, the over-molded PCB can be attached to the cell leads of the battery cell(s). This may be done in a normal orientation or in a reversed orientation as described above. If the over-molded PCB is attached to the battery cell(s) in a rotational position other than the final position, in block 440, the over-molded PCB may be rotated into its final position. In block 442, the over-molded PCB may be secured to the battery pack, using an adhesive, tape, or other affixing method.

### CONCLUSION

Described above are various features and embodiments relating to over-molded printed circuit boards for use with battery assemblies for electronic devices. Such assemblies may be used in a variety of applications, but may be particular advantageous when used in conjunction with portable electronic devices such as mobile telephones, smart phones, tablet computers, laptop computers, media players, and the like, as well as the peripherals associated therewith. Such associated peripherals can include input devices (such as keyboards, mice, touchpads, tablets, and the like), output devices (such as headphones or speakers), storage devices, or any other peripheral.

Additionally, although numerous specific features and various embodiments have been described, it is to be understood that, unless otherwise noted as being mutually exclusive, the various features and embodiments may be combined in any of the various permutations in a particular implementation. Thus, the various embodiments described above are provided by way of illustration only and should not be constructed to limit the scope of the disclosure. Various modifications and changes can be made to the principles and embodiments herein without departing from the scope of the disclosure and without departing from the scope of the claims.

1. An over-molded printed circuit board for use in a battery pack, the over-molded printed circuit board comprising:
a printed circuit board having one or more electronic components disposed thereon;
a flex connector attached to the printed circuit board; and
an over-mold formed about the printed circuit board, wherein the over-mold facilitates routing of the flex connector at a desired angle from the battery pack.

2. The over-molded printed circuit board of claim 1 wherein the one or more electronic components comprise battery management circuitry configured to provide information about one or more of battery cell current, battery cell voltage, and battery cell temperature.

3. The over-molded printed circuit board of claim 1 wherein the flex connector comprises a inter-board connector.

4. The over-molded printed circuit board of claim 1 wherein one or more surfaces of the over-mold have a geometry that provides a supporting mechanical interface between the one or more battery cells and the printed circuit board.

5. The over-molded printed circuit board of claim 1 wherein the over-mold is formed by injection molding an epoxy resin about the printed circuit board.

6. The over-molded printed circuit board of claim 1 wherein the over-mold comprises a plurality of test ports allowing electrical connection to test terminals located on the printed circuit board.

7. A battery pack, the battery pack comprising:
one or more battery cells;
a printed circuit board having one or more electronic components disposed thereon;
a flex connector attached to the printed circuit board; and
an over-mold formed about the printed circuit board, wherein the over-mold facilitates routing of the flex connector at a desired angle from the battery pack and wherein one or more surfaces of the over-mold have a geometry that provides a supporting mechanical interface between the one or more battery cells and the printed circuit board.

8. The battery pack of claim 7 wherein the one or more electronic components comprise battery management circuitry configured to provide information about one or more of battery cell current, battery cell voltage, and battery cell temperature.

9. The battery pack of claim 7 wherein the flex connector comprises a inter-board connector.

10. The battery pack of claim 7 further comprising an adhesive tape securing the over-mold and the printed circuit board to the battery pack.

11. The battery pack of claim 7 wherein the over-mold is formed by injection molding an epoxy resin about the printed circuit board.

12. The battery pack of claim 7 wherein the over-mold comprises a plurality of test ports allowing electrical connection to test terminals located on the printed circuit board.

13. The battery pack of claim 7 further comprising a plastic cap disposed adjacent the over-mold and configured to protect the over-mold and the printed circuit board during assembly of the battery pack.

14. A method of assembling a battery pack, the method comprising:
assembling a printed circuit board;
attaching a flex connector to the printed circuit board;
over-molding the printed circuit board to form an overmold, wherein the overmold is configured to provide at least one of:
routing of the flex connector at a desired angle from the battery pack; or
providing a supporting mechanical interface between one or more components of the battery pack and the printed circuit board; and
attaching the over-molded printed circuit board to one or more cell leads of the battery pack.

15. The method of claim 14 further comprising rotating the over-molded printed circuit board and mechanically affixing the over-molded printed circuit board to the battery pack.

16. The method of claim 15 wherein the over-molded printed circuit board is affixed to the battery pack by an adhesive tape.

17. The method of claim 16 further comprising disposing a plastic cap between the adhesive tape and the over-molded printed circuit board.

18. The method of claim 14 wherein assembling the printed circuit board comprises installing one or more electronic components comprising battery management circuitry configured to provide information about one or more of battery cell current, battery cell voltage, and battery cell temperature.

19. The method of claim 14 wherein over-molding the printed circuit board comprises injection molding an epoxy resin about the printed circuit board.

20. The method of claim 14 wherein over-molding the printed circuit board comprises forming a plurality of test ports through the over-mold, the test ports allowing electrical connection to test terminals located on the printed circuit board.
